(19) United States
(12) Patent Application Publication
(10) Pub. No.: US 2006/0170053 A1
(43) Pub. Date: Aug. 3, 2006

(54) Accumulation mode multiple gate transistor

(76) Inventors: Yee-Chia Yeo, Hsinchu (TW); Fu-Liang Yang, Hsinchu (TW); Chenming Hu, Hsinchu (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 10/434,618

(22) Filed: May 9, 2003

(51) Int. Cl. H01L 27/12

(52) U.S. Cl. 257/353

(57) ABSTRACT

A transistor (1) having, a fin (2) and a gate electrode (3) extending on more than one side of the fin (2) to comprise more than one gate (9) of the transistor (1), and a dopant in each of a source (6), drain (7) and a channel region (8), comprising a single dopant type.

### FIELD OF THE INVENTION

The present invention relates to a multiple gate transistor having a fin comprising a source and a drain, and a gate electrode that extends on more than one side of the fin to comprise more than one gate of the transistor. More particularly, the present invention relates to a multiple-gate transistor with source, drain, and channel regions with the same doping type.

### BACKGROUND

U.S. Pat. No. 6,413,802 discloses a multiple gate transistor having a fin comprising a source and a drain of the transistor, and a gate electrode extending on two sides of the fin to comprise two gates of the transistor. Thus, the patent discloses an embodiment of a multiple gate transistor comprising a double gate transistor.

The multiple gate transistor has a channel region between the source and the drain, and comprises a barrier to leakage currents that tend to flow from the source to the drain. However, when the transistor is made desirably smaller, the source and drain increasingly interact with the channel and result in a reduced barrier to leakage currents. This increases the likelihood of leakage currents, one of the undesired effects that are referred to as, short channel effects.

Multiple gates on a transistor improve capacitance coupling between the gates and the channel region, increases the influence of gate-control of the channel region potential for control of threshold voltage and floating voltage bias on the transistor, and for suppresses short channel effects.

In prior transistors, as disclosed by U.S. Pat. No. 6,344,405, the channel region comprises a first dopant type, and the implant for the source and drain regions comprises a different dopant type. For an N-channel MOSFET, metal oxide silicon field effect transistor, the channel region is doped P-type, while the source and drain regions are doped N-type. For a P-channel MOSFET, the channel region is doped N-type, while the source and drain regions are doped P-type. Application of a gate bias voltage that switches the transistor to an on state, causes inversion of the channel region, resulting in formation of N-type carriers or electrons in a P-type channel region, or resulting in formation of P-type carriers or electrons in a N-type channel region. Each of these types of transistors having both P and N dopant types comprises an enhancement mode transistor.

When multiple gate transistors are scaled down to small dimensions, it becomes increasingly difficult to form transistors comprised of regions with different dopant types directly adjacent to each other. For example, for a gate length of 10 nm., nanometers, the channel region volume comprises, about 10⁻¹⁸ cm³, and measures about 10 nm. in each of three orthogonal dimensions. In such a small transistor channel region, the introduction of a dopant atom is equivalent to a doping concentration of 1×10¹⁸ dopants cm⁻³and above. When the channel region comprises a first dopant type and the implant comprises a different dopant type, the large dopant concentration by each atom of dopant in the channel region may significantly change the doping concentration in the channel region and result in deleterious effects in the transistor performance. For example, one deleterious effect is the significant lowering of the threshold voltage and the associated high leakage current when the transistor is in the off state.

### SUMMARY OF THE INVENTION

The present invention comprises a multiple gate transistor comprising a semiconductor fin having a source, drain and channel regions comprising solely a single dopant type, by which the transistor avoids an undesired large doping concentration contributed by each atom of dopant in the channel region. The present invention comprises a method of manufacturing a transistor according to the present invention.

### BRIEF DESCRIPTION OF THE DRAWINGS

FIG. 1 is a perspective view of an embodiment of a transistor, as an elemental semiconductor, or, alternatively, as part of a compound semiconductor.

FIG. 2 is a cross section taken along the line A-A of FIG. 1.

FIG. 3A is a view of a cross section taken along the line B-B of FIG. 1, and disclosing an accumulation mode N-channel FET.

FIG. 3B is a view of a cross section of an accumulation mode P-channel FET present on the same substrate with the transistor disclosed by FIG. 3A.

FIG. 3C is a view of a cross section of an enhancement mode P-channel FET present on the same substrate with the transistor disclosed by FIG. 3A.

FIG. 4 is a perspective view of another embodiment of a transistor, as an elemental semiconductor, or, alternatively, as part of a compound semiconductor.

FIG. 5 is a view of a cross section taken along the line A-A of FIG. 4.

FIG. 6A is a view of a cross section taken along the line B-B of FIG. 4.

FIG. 6B is a view of a cross section of an accumulation mode P-channel FET present on the same substrate with the transistor disclosed by FIG. 6A.

FIG. 7 is a cross section taken along the line C-C of FIG. 4.

FIG. 8 is a perspective view of another embodiment of a transistor, as an elemental semiconductor, or, alternatively, as part of a compound semiconductor.

FIG. 9 is a perspective view of another embodiment of a transistor, as an elemental semiconductor, or, alternatively, as part of a compound semiconductor.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,”etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

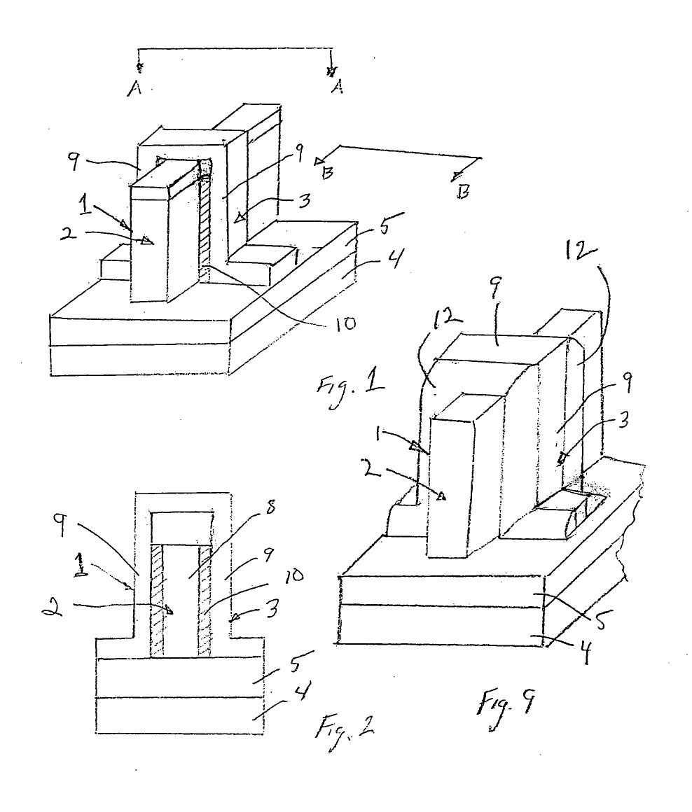

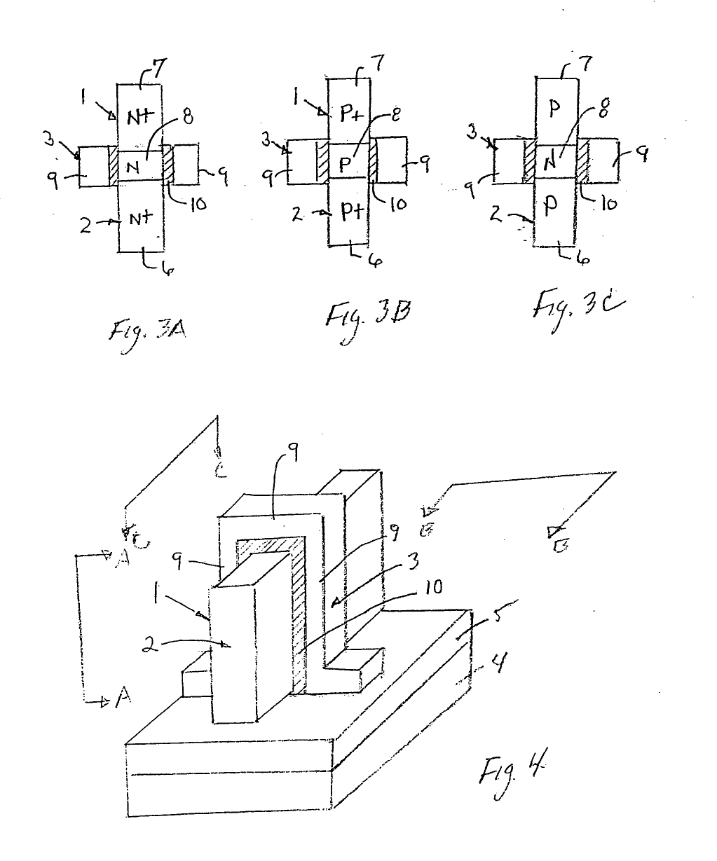

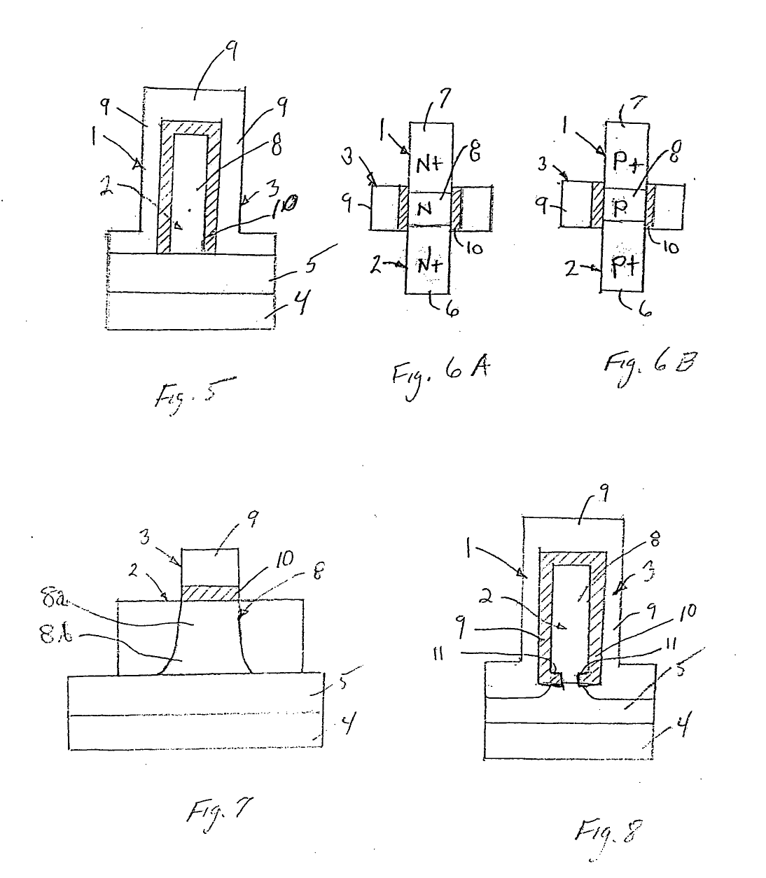

According to the invention, each of FIGS. 1, 4, 8 and 9 discloses a multiple gate transistor (1) comprising a semiconductor fin (2) and an insulation supported gate electrode (3) constructed on an electrically insulating substrate (4) having an interlayer (5) overlying the substrate (4) and electrically isolating the transistor (1) from the substrate (4). As disclosed by FIGS. 3A, 3B, 3C, 6A and 6B, the fin (2) comprises a transistor source (6), a transistor drain (7) and an insulating channel region (8) between the source (6) and the drain (7). The insulation supported gate electrode (3) extends on more than one side of the fin (2) to comprise more than one gate (9) of the transistor (1) against the channel region (8). The channel region (8) extends between the source (6) and the drain (7) in a longitudinal direction.

FIG. 1 discloses an embodiment of the invention. A multiple gate transistor (1) comprises, at least, first and second transistor gates (9) by extending the gate electrode (3) on opposed sidewalls of the fin (2), and against corresponding sides of the channel region (8). An insulating mask (9a) covers a top side of the channel region (8) and separates the channel region (8) from connection with the gate electrode (3). Further, the gate electrode (3) overlies a thin gate dielectric (10) that is between the gate electrode (3) and the channel region (8), which provides a semiconductor barrier between each gate (9) and the channel region (8). A transistor (1) having first and second gates (9), is referred to as, a double gate transistor (1). An FET type of transistor having double gates (9) is referred to as, a double gate FET.

FIG. 4 discloses another embodiment of the invention. The gate electrode (3) comprises a first gate (9) and a second gate (9), similarly as disclosed with reference to FIG. 1. Further, the gate electrode (3) comprises a third transistor gate (9) by extending on a top side of the fin (2), and against a corresponding top of the channel region (8). Further, the gate electrode (3) overlies a thin gate dielectric (10) that is between the gate electrode (3) and the channel region. The thin gate dielectric (10) also provides a barrier between the third gate (9) and the channel region (8). A transistor (1) having first, second and third gates, is referred to as, a triple gate transistor (1). An FET type of transistor (1) having triple gates (9) is referred to as, a triple gate FET.

FIG. 8 discloses another embodiment of the invention. The gate electrode (3) comprises gate extensions (11) under the fin (2) that increase gate control by lengthening the gate (9) to cover further portions of the channel region (8). The encroachment of the gate electrode under the silicon body helps to shield the channel from electric field lines from the drain and improves gate-to-channel controllability, thus alleviating the drain-induced barrier lowering effect and improving short-channel performance. The gate extensions (11) extend part way into the channel region. The gate extensions (11) extend toward each other in a longitudinal direction. When the gate extensions (11) are constructed on the triple gate transistor (1) of the invention, the triple gates (9) have a cross section with an Omega shaped appearance, and is referred to as, an omega transistor (1). An FET transistor (1) having a triple gate (9) with the gate extensions (11) is referred to as, an omega-FET.

FIG. 9 discloses an alternative embodiment wherein, a silicon spacer (12) comprises side walls of silicon against an outer side wall of each gate (9). The silicon spacer (12) provides an electrical isolation barrier covering opposite sides of the gate electrode (3). The spacer material comprises a dielectric material, including but not limited to, silicon oxide, silicon oxynitride, silicon nitride, or a combination thereof. The spacer material alternatively comprise, a stack of different spacer materials stacked one on another.

FIG. 7 discloses an embodiment of the channel region (8) comprising a shallow channel region (8a) and a deep channel region (8b) that is longer than the shallow channel region (8a) in the longitudinal direction.

As disclosed by each of FIGS. 3A and 6A, an embodiment of the present invention comprises, an N-channel mode transistor (1) that comprises an N⁺; N; N+ doped silicon fin (2) comprising, an N doped channel region (8) between an N+ doped source (6) and an N+ doped drain (7). Further, as disclosed by FIGS. 3B and 6B, an alternative embodiment of the present invention comprises, a P-channel mode transistor that comprises a P-type doped silicon fin (2), in turn, comprising, an P doped channel region (8) between a P+ doped source (6) and a P+ doped drain (7). A transistor (1) having a fin (2) with a single doping type, either an N-dopant type or a P-dopant type, is referred to as an accumulation mode transistor (1). An N-doped transistor of this type is referred to as an N-channel accumulation mode transistor (1). A P-doped transistor of this type is referred to as a P-channel accumulation mode transistor (1).

With reference to FIG. 6A, the operation of an exemplary accumulation mode transistor (1) will now be described. At an off state, the voltage of the gate (9) is the same as the voltage of the source (6), while the channel region (8) has a depletion region that is depleted of mobile charge carriers, i.e., electrons, and therefore suppresses conduction of current from the source (6) to the drain (7).

In a sub threshold state, a voltage of sub threshold level biases the gate (9) with respect to the voltage level of the source (6). The depletion region in the channel region (8) shrinks, while electrons populate an undepleted channel region (8) near the source (6), causing the undepleted channel region (8) to expand by shrinking the depletion region near the drain (7). When a small voltage difference exists between the undepleted channel region (8) and the drain (7), a low level current will flow therebetween without turning the transistor (1) on.

An on state of the transistor (1) is attained when the gate (9) is biased by a voltage level, relative to voltage level of the source (6), that exceeds the threshold voltage level of a bias voltage that is necessary to turn on the transistor (1). Depletion regions in the channel region (8) are replaced by accumulation regions that accumulate and contain a high level of mobile charge carriers accumulating near the gate dielectric (10) and the gate (9). A desired high current level is conducted from the source (6) to the drain (7) via the accumulation regions.

The fin (2) comprises an elemental semiconductor material, including but not limited to, silicon or germanium, an alloy semiconductor material, for example, silicon-germanium, or a compound semiconductor material, for example, gallium arsenide or indium phosphide.

The gate electrode (3) material comprises, a conducting material, including but not limited to, polycrystalline-silicon, poly-crystalline silicon-germanium.

The gate dielectric (10) comprises a dielectric material with a permittivity larger than 8, which comprises a high-k dielectric material, including but not limited to, lanthalum oxide La₂O₃, aluminum oxide Al₂O₃, hafnium oxide HfO₂, hafnium oxynitride HfON, zirconium oxide, ZrO₂, or zirconium oxynitride ZrON, and combinations thereof. with a thickness providing an equivalent isolation as does less than 100 Angstroms of silicon oxide.

Each of the multiple gate, accumulation mode transistors (1) is manufactured by performance of a corresponding process according to the invention. According to another embodiment of a process according to the invention, multiple accumulation mode transistors (1) are manufactured simultaneously. According to another embodiment of a process according to the invention, both an N-channel accumulation mode transistor (1) and a P-channel accumulation mode transistor (1) are manufactured together, when they are on the same substrate (4). According to another embodiment of a process according to the invention, an accumulation mode transistor (1) is manufactured in the presence of an enhancement mode transistor that is present with the accumulation mode transistor (1) on the same substrate (4).

A process for manufacture of an accumulation mode N-channel transistor (1) and/or an enhancement mode P-channel transistor will now be described. The starting material is a semiconductor interlayer (5) for manufacture of fins (2) deposited on the substrate (4) made of silicon, by way of example only.

The semiconductor layer for manufacture of the fins (2) comprises, silicon, an alloy semiconductor, such as, silicon-germanium, or a compound semiconductor, such as, gallium arsenide or indium phosphide, having a thickness in the range of 200 Angstroms to 5000 Angstroms, by way of example only.

The interlayer (5) comprises a dielectric or insulator, for example, silicon oxide or silicon nitride, having a thickness in the range of 100 to 2000 Angstroms, by way of example only.

According to an embodiment, a semiconductor layer of silicon is deposited on an interlayer (5) of silicon oxide, in turn, which has been deposited on the substrate (4) of silicon.

Multiple fins (2) are formed by depositing a mask comprising, photoresist or silicon oxide resist over the semiconductor layer, followed by patterning the mask with openings to expose portions of the semiconductor for removal by etching, and etching the exposed portions of the semiconductor layer, of silicon, for example, which constructs multiple fins (2). The mask is removed to reveal the fins (2).

To manufacture accumulation mode N-channel transistors (1), end portions of each of the fins (2) are doped with N+ dopant through openings in a patterned mask, for example, by ion implantation, and the semiconductor layer of silicon is N doped through openings in another patterned mask, for example, by ion implantation. To manufacture accumulation mode P-channel transistors, end portions of each of the fins (2) are doped with P+ dopant, for example, by ion implantation, and the semiconductor layer of silicon is P doped for example, by ion implantation. Thus, each accumulation mode transistor (1) is manufactured with an ion dopant of +ions in end portions of each fin (2), and with an ion dopant of the same dopant type in the channel region (8) of each fin (2).

A thin layer of material, by which each gate dielectric (10) is formed, is formed to cover the fins (2), for example, by, thermal oxidation, chemical vapor deposition, sputtering, or any known process of coating.

A layer of conducting material by which each gate electrode (3) is formed, is formed to cover the previously covered fins (2), by a process, including but not limited to, chemical vapor deposition, to have a thickness in the range of 500 Angstroms to 4000 Angstroms. further, the material for each gate electrode (3) is undoped, or is doped with relatively few dopant atoms. The material for each gate electrode (3) may have work function implants that alter the localized physics of the material. In an embodiment of the present invention, the material comprises, undoped polysilicon with a thickness of about 2000 Angstroms.

A mask is applied over the layer of material for each gate electrode (3). The mask is patterned with openings to expose portions of the layer of conducting material for removal by etching. Etching, including a plasma etching process, is performed to remove the portions of the layer of conducting material, to form unetched, gate electrodes (3). Etching is halted, either when the gate dielectric (10) has been substantially removed by being etched, or when the gate dielectric material comprises a stop etch composition that suppresses further etching. The mask is removed to reveal the gate electrodes (3).

Residues of the gate dielectric material, when present, on the silicon fins (2) are removed by a compatible etchant that selectively etches the gate dielectric material, exposing the source (6) and drain (7) of each fin (2) for further processing.

When enlargement of the exposed source (6) and drain (7) sections of corresponding fins (2) is desired, selective epitaxy is performed to enlarge them, while the gate electrode (3) material covers corresponding channel regions (8) in the fins (2) to suppress enlargement thereof.

When improved conductivity is desired for the source (6), drain (7) and gates (9) of corresponding fins (2), one or more conducting materials are selectively deposited thereon, for example, by deposition through openings in a patterned mask. The conductive material includes but is not limited to a silicide of metals. such as, tungsten, titanium, cobalt, nickel, platinum, erbium, or combinations thereof, by way of example only.

The source (6) and the drain (7) for each fin (2) is manufactured, for example, by ion implantation or plasma immersion. Each accumulation mode P-channel transistor (1), that is present on the same substrate (4), and each enhancement mode transistor that is present on the same substrate (4), are covered by a patterned mask, while a fin (2) of each enhancement mode N-channel transistor (1) is simultaneously exposed through a corresponding opening in the mask for simultaneous implantation of N dopant in the channel region (8) of each corresponding fin (2), and further, for simultaneous implantation of N+ dopant in the end portions of each corresponding fin (2).

Alternatively, each accumulation mode N-channel mode transistor (1) that may be present, and each enhancement mode transistor that is present on the same substrate (4) is covered by a corresponding patterned mask, while each fin (2) for forming an accumulation mode P-channel transistor (1) is exposed through a corresponding opening in the patterned mask for simultaneous implantation of P dopant in the channel region (8) of each corresponding fin (2), and further, for simultaneous implantation of P+ dopant in the end portions of each corresponding fin (2). The channel region (8) has the same doping concentration as the source (6) or drain (7). Each enhancement mode transistor is formed by diffusing dopants from the source and drain to form a channel region of a second dopant type.

Annealing is performed to activate the dopants.

The spacers (12) are formed on the sidewalls of each gate electrode (3) according to the following process steps. Spacer material is deposited on each gate electrode (3), followed by applying a photoresist mask and patterning the mask with openings for exposing portions of the spacer material for removal by etching, followed by, etching to remove the portions of the spacer material from all surfaces except for the sidewalls of each gate electrode (3). Etching is advantageously performed by an anisotropic etchant that etches in one orthogonal direction, significantly faster, than in another direction.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention

What is claimed is:

1. A semiconductor chip comprising:
an accumulation mode multiple-gate transistor, said transistor comprising at least one semiconductor fin overlying an insulator,
each said semiconductor fin comprising a source region, a drain region, and a channel region, which comprise semiconductor materials of a first doping type;
a gate dielectric overlying the channel region; and
a multiple gate electrode overlying the gate dielectric.

2. The semiconductor chip of claim 1 further comprising:
an enhancement mode multiple-gate transistor overlying the insulator.

3. The semiconductor chip of claim 2 wherein the accumulation mode multiple-gate transistor is a N-channel transistor and the enhancement mode multiple-gate transistor is a P-channel transistor.

4. The semiconductor chip of claim 2 wherein the accumulation mode multiple-gate transistor is a P-channel transistor and the enhancement mode multiple-gate transistor is a N-channel transistor.

5. An accumulation mode multiple-gate transistor comprising:
a first semiconductor fin overlying an insulator,
said semiconductor fin comprising a source region, a drain region, and a channel region, said source, drain, and channel regions, which comprise semiconductor materials having the same doping type;
a gate dielectric overlying the channel region; and
a gate electrode overlying the gate dielectric.

6. The transistor of claim 5 wherein the semiconductor comprises an elemental semiconductor.

7. The transistor of claim 5 wherein the semiconductor comprises a compound semiconductor.

8. The transistor of claim 5 wherein the semiconductor comprises silicon.

9. The transistor of claim 5 wherein the first doping type is N-type.

10. The transistor of claim 5 wherein the first doping type is P-type.

11. The transistor of claim 5 wherein the channel region has a doping concentration above 10¹⁸ cm⁻³.

12. The transistor of claim 5 wherein the channel region has a same doping concentration as the doping concentration in the source or drain regions.

13. The transistor of claim 5 wherein the gate dielectric comprises silicon oxide, silicon oxynitride, or silicon nitride.

14. The transistor of claim 5 wherein the gate dielectric comprises a dielectric with a permittivity larger than 8.

15. The transistor of claim 5 wherein the gate dielectric has a thickness of less than 100 angstroms.

16. The transistor of claim 5 further comprising spacers on the sides of the gate electrode.

17. The transistor of claim 5 wherein the multiple-gate transistor is a double-gate transistor.

18. The transistor of claim 5 wherein the multiple-gate transistor is a triple-gate transistor.

19. The transistor of claim 5 wherein the multiple-gate transistor is a omega field-effect transistor.

20. A method of forming a semiconductor chip with an accumulation mode multiple-gate transistor comprising the steps of:
a) providing a semiconductor structure comprising a semiconductor fin of a first doping type overlying an insulator layer of a semiconductor chip;
b) forming a gate dielectric overlying a portion of said semiconductor fin;.
c) forming a gate electrode overlying said gate dielectric; and
d) forming a source and a drain region of the first doping type to form the accumulation mode multiple-gate transistor.

21. The method of claim 20 further comprising the steps of:
e) forming spacers on the sides of the gate electrode; and
f) forming a silicide on the source and drain region.

22. The method of claim 20 further comprising a step, before the step of forming a source and a drain region, of:
performing selective epitaxy on the portions of the semiconductor fin not covered by the gate electrode;

23. The method of claim 20 wherein the source and drain regions are formed by ion implantation or plasma immersion ion implantation.

24. The method of claim 20 wherein the step of forming the gate electrode comprises a plasma etching process.

25. A method of forming a semiconductor chip with multiple-gate transistors comprising the steps of:
a) providing a semiconductor structure comprising a first semiconductor fin and a second semiconductor fin, both semiconductor fins comprising semiconductor materials of a first doping type, both semiconductor fins overlying an insulator layer;
b) forming a gate dielectric overlying a portion of each semiconductor fin;
c) forming a gate electrode overlying said gate dielectric;
d) forming a source and a drain region of the first doping type in a portion of the first semiconductor fin to form the accumulation mode multiple-gate transistor;
e) forming a source and a drain region of a second doping type in a portion of the second semiconductor fin to form an enhancement mode multiple-gate transistor.

26. The method of claim 25 further comprising the steps of:
f) forming spacers on the sides of the gate electrode; and
g) forming a silicide on the source and drain region.

27. The method of claim 25 further comprising a step, before the step of forming a source and a drain region, of
performing selective epitaxy on the portions of the semiconductor fin not covered by the gate electrode.

28. The method of claim 25 wherein the source and drain regions are formed by ion implantation or plasma immersion ion implantation.

29. The method of claim 25 wherein the step of forming the gate electrode comprises a plasma etching process.

30. A method of forming a semiconductor chip with accumulation mode multiple-gate transistors comprising the steps of:
a) providing a semiconductor structure comprising a first semiconductor fin of a first doping type and a second semiconductor fin of a second doping type, both semiconductor fins overlying an insulator layer;
b) forming a gate dielectric overlying a portion of each semiconductor fin;
c) forming a gate electrode overlying said gate dielectric;
d) forming a source and a drain region of the first doping type in a portion of the first semiconductor fin to form a first accumulation mode multiple-gate transistor; and
e) forming a source and a drain region of the second doping type in a portion of the second semiconductor fin to form a second accumulation mode multiple-gate transistor.

31. The method of claim 30 further comprising the steps of:
f) forming spacers on the sides of the gate electrode;
g) forming a silicide on the source and drain region.

32. The method of claim 30 further comprising a step, before the step of forming a source and a drain region, of:
performing selective epitaxy on the portions of the semiconductor fin not covered by the gate electrode.

33. The method of claim 30 wherein the source and drain regions are formed by ion implantation or plasma immersion ion implantation.

34. The method of claim 30 wherein the step of forming the gate electrode comprises a plasma etching process.
